(19) United States
(12) Patent Application Publication
(10) Pub. No.: US 2024/0190902 A1
(43) Pub. Date: Jun. 13, 2024

(54) FREE-RADICALLY POLYMERIZABLE MONOMER, FREE-RADICALLY POLYMERIZABLE COMPOSITION, METHOD OF USING THE SAME, POLYMERIZED COMPOSITION, AND ELECTRONIC ARTICLE

(71) Applicant: 3M INNOVATIVE PROPERTIES COMPANY, St. Paul, MN (US)

(72) Inventors: Claire Hartmann-Thompson, Lake Elmo, MN (US); Evan L. Schwartz, Vadnais Heights, MN (US)

(21) Appl. No.: 18/577,583

(22) PCT Filed: Jun. 22, 2022
(86) PCT No.: PCT/IB2022/055808

§ 371 Date: Jan. 8, 2024

Related U.S. Application Data
(60) Provisional application No. 63/221,211, filed on Jul. 13, 2021.

(51) Int. Cl. C07F 7/18; C08F 30/08; C09D 11/101; C09D 11/30; H10K 59/80

(52) U.S. Cl. CPC C07F 7/1804; C08F 30/08; C09D 11/101; C09D 11/30; H10K 59/873

(57) ABSTRACT

A free-radically polymerizable monomer is represented by the formula Each Z independently represents a divalent aliphatic hydrocarbylene group having 3 to 12 carbon atoms. Each R¹ independently represents H or methyl. Each R² independently represents a hydrocarbyl group having from 1 to 6 carbon atoms. R³ represents methyl, phenyl, or —CH₂CH₂CF₃, and n is 3 or 4. A free-radically polymerizable composition comprises the free-radically polymerizable monomer and a free-radical polymerization initiator. A method of using the free-radically polymerizable composition, an at least partially polymerized composition, and an electronic article are also disclosed.

### TECHNICAL FIELD

The present disclosure broadly relates to free-radically polymerizable monomers, free-radically polymerizable compositions including them, and methods of using the same.

### BACKGROUND

The trend in organic light emitting diode (OLED) manufacture is to fabricate more and more layers via ink jet printing, especially the thin film encapsulation layers that prevent air and moisture ingress into the OLED device. This requires that encapsulants (inks) be deliverable in a low viscosity liquid (inkjet printable) form, while also maintaining the following target properties: high transmission and low color; high purity (free of water and halides); etch resistance (against plasma deposition used in thin film encapsulation (TFE)); complete UV-cure for minimal outgassing; high glass transition temperature (Tg) to meet thermal resistance specifications; and optimum ink spread (versus zero spread or excessive spread).

Commonly, thin film encapsulation (TFE) layers are used to prevent air and moisture ingress into OLED devices. The TFE is typically composed of alternating layers of inorganic and organic materials (e.g., see Chwang et al., Applied Physics Letters, 2003, 83, 413-415). The function of the inorganic layers is to act to block the ingress of air and moisture into the OLED device. The functions of the organic layer(s) are twofold: 1) to planarize the substrate and present a smooth interface for the deposition of the inorganic layer; and 2) to decouple any defects (pinholes, micro-cracks) that may occur in the inorganic layers on either side of the organic layer. The organic layer can be thought of as a buffer layer that is critical for the success of the inorganic layer barrier function.

### SUMMARY

The present disclosure provides new and useful free-radically polymerizable materials having low dielectric constant and/or low dielectric loss characteristics suitable for use in 5G enabled wireless telecommunication devices, for example in inkjet printable OLED encapsulant inks.

The materials have one or more, often all, of the following combination of benefits: (1) low viscosity, (2) low dielectric constant, (3) etch resistance to plasma conditions encountered during OLED fabrication, (4) reduced volatile potentially-outgassing content via covalent cure of at least one functional group into the layer, (5) high glass transition temperature of cured layers (>100° C.) to minimize cracking and delamination in high temperature/high humidity rapid aging (RA) conditions, (6) tailorable refractive index. Advantageously, they may also be free of volatile organic solvents.

In one aspect, the present disclosure provides a free-radically polymerizable monomer represented by the formula

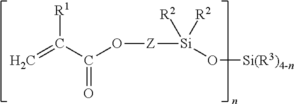

wherein:
each Z independently represents a divalent aliphatic hydrocarbylene group having 3 to 12 carbon atoms;
each R¹ independently represents H or methyl;
each R² independently represents a hydrocarbyl group having from 1 to 6 carbon atoms;
R³ represents methyl, phenyl, or —CH₂CH₂CF₃; and
n is 3 or 4.

The free-radically polymerizable monomer is useful, for example, in free-radically polymerizable compositions. Accordingly, in another aspect, the present disclosure provides a free-radically polymerizable composition comprising:
i) a free-radically polymerizable monomer represented by the formula

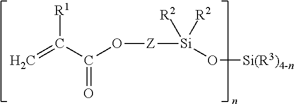

wherein:
   each Z independently represents a divalent aliphatic hydrocarbylene group having 3 to 12 carbon atoms;
   each R¹ independently represents H or methyl;
   each R² independently represents a hydrocarbyl group having from 1 to 6 carbon atoms;
   R³ represents methyl, phenyl, or —CH₂CH₂CF₃; and
   n is 3 or 4; and
ii) a free-radical polymerization initiator.

In yet another aspect, the present disclosure provides a method of using the free-radically polymerizable composition according to the present disclosure, the method comprising disposing the free-radically polymerizable composition on a substrate, and decomposing at least a portion of the free-radical polymerization initiator thereby causing at least partial polymerization of the free-radically polymerizable composition.

In yet another aspect, the present disclosure provides an at least partially polymerized free-radically polymerizable composition according to the present disclosure.

In yet another aspect, the present disclosure provides an electronic article comprising an at least partially polymerized free-radically polymerizable composition according to the present disclosure at least partially encasing an optical electronic component.

As used herein, the term “(meth)acryl” refers to acryl and/or methacryl.

Features and advantages of the present disclosure will be further understood upon consideration of the detailed description as well as the appended claims.

### BRIEF DESCRIPTION OF THE DRAWING

FIG. 1 is a schematic side view of an exemplary electronic article 100.

It should be understood that numerous other modifications and embodiments can be devised by those skilled in the art, which fall within the scope and spirit of the principles of the disclosure. The figures may not be drawn to scale.

### DETAILED DESCRIPTION

The free-radically polymerizable monomer is represented by the formula

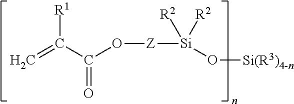

Each Z independently represents a divalent aliphatic hydrocarbylene group having 3 to 12 carbon atoms, preferably 3 to 6 carbon atoms. Examples include: propane-1,3-diyl; propane-1,2-diyl; butane-1,4-diyl; butane-1,3-diyl; butane-1,2-diyl; pentane-1,5-diyl; hexane-1,6-diyl; cyclohexane-1,4-diyl; heptane-1,7-diyl; octane-1,8-diyl; nonane-1,9-diyl; decane-1,10-diyl; undecane-1,11-diyl; and dodecane-1,12-diyl.

Each R¹ independently represents H or methyl. In some preferred embodiments, R¹ is methyl.

Each R² independently represents a hydrocarbyl group having from 1 to 6 carbon atoms. Examples include methyl, ethyl, n-propyl, isopropyl, n-butyl, isobutyl, n-pentyl, isopentyl, neopentyl, n-hexyl, cyclohexyl, and phenyl.

R³ represents methyl, phenyl, or —CH₂CH₂CF₃.

The value of n is 3 or 4, which implies 4-n is 1 or 0. In this context, a value of n=4 means that no R³ group is present, while a value of n=3 means that a single R³ group is present.

The free-radically polymerizable monomer can be made, for example, by hydrosilylation of an appropriate polyhydropolysiloxane precursor with a terminal alkenyl (meth)acrylate, generally in the presence of a hydrosilylation catalyst.

Exemplary hydrosilylation catalysts include a platinum divinyltetramethyldisiloxane complex (Karstedt's catalyst), H₂PtCl₆ (Speier's catalyst), and Wilkinson's catalyst. Numerous hydrosilylation catalysts are known in the art, and many are commercially available; for example, from Gelest, Inc., Morrisville, Pennsylvania.

Useful terminal alkenyl (meth)acrylates can be made by well-known techniques (e.g., condensation, transesterification) from (meth)acrylic acid or a derivative thereof (e.g., a methyl ester or acid chloride) with a terminal alkenyl alcohol. Suitable terminal alkenyl alcohols include allyl alcohol, 3-buten-1-ol, 4-penten-1-ol, 5-hexen-1-ol, 6-hepten-1-ol, 7-octen-1-ol, 8-nonen-1-ol, 9-decen-1-ol, 10-undecen-1-ol, and 11-dodecen-1-ol, all of which are known and commercially available.

Polyhydropolysiloxanes can be made according to known methods and/or obtained from commercial suppliers such as Gelest, Inc.; ABCR, Karlsruhe, Germany; and MilliporeSigma, Burlington, Massachusetts. Examples include tetrakis(dimethylsiloxy)silane, methyltri(dimethylsiloxy)silane, phenyltri(dimethylsiloxy)silane, and trifluoropropyltris(dimethylsiloxy)silane.

The free-radically polymerizable monomer may be included in a free-radically polymerizable composition in combination with at least a free-radical polymerization initiator and optionally at least one other free-radically polymerizable monomer. Exemplary free-radically polymerizable monomers can have one, two, three, four, five, six, or more free-radically polymerizable groups.

Exemplary mono-functional free-radically polymerizable monomers include (meth)acrylamides (e.g., (meth)acrylamide, N-methyl (meth)acrylamide, N-ethyl (meth)acrylamide, N-hydroxyethyl (meth)acrylamide, diacetone (meth)acrylamide, N,N-dimethyl (meth)acrylamide, N,N-diethyl (meth)acrylamide, N-ethyl-N-aminoethyl (meth)acrylamide, N-ethyl-N-hydroxyethyl (meth)acrylamide, N,N-dihydroxyethyl (meth) acrylamide, t-butyl (meth)acrylamide, N,N-dimethylaminoethyl (meth)acrylamide, and N-octyl (meth)acrylamide), (meth)acrylates (e.g., 2,2-(diethoxy)ethyl (meth)acrylate, 2-hydroxyethyl (meth)acrylate, caprolactone (meth)acrylate, 3-hydroxypropyl (meth)acrylate, methyl (meth)acrylate, isobornyl (meth)acrylate, 2-(phenoxy)ethyl (meth)acrylate, biphenyl methyl (meth)acrylate, t-butylcyclohexyl (meth)acrylate, cyclohexyl (meth)acrylate, dimethyladamantyl (meth)acrylate, 2-naphthyl (meth)acrylate, phenyl (meth)acrylate, benzyl (meth)acrylate, phenoxyethyl (meth)acrylate, tetrahydrofurfuryl (meth)acrylate, t-butyl (meth)acrylate, 2,3,3-trimethyl buten-2yl-acrylate, lauryl (meth)acrylate, stearyl (meth)acrylate and its branched isomers, n-hexyl (meth)acrylate, cyclic trimethylolpropane formal (meth)acrylate, 3,3,5-trimethyl cyclohexyl (meth)acrylate, isopropyl (meth)acrylate, and ethylhexyl (meth)acrylate); N-vinyl pyrrolidinone, and N-vinyl caprolactam.

Monomers having multiple free-radically polymerizable groups include, for example, di(meth)acrylates, tri(meth)acrylates, and tetra(meth)acrylates. Examples include 1,6-hexanediol di(meth)acrylate, 1,4-butanediol di(meth)acrylate, 1,10-decanediol di(meth)acrylate, 1,12-dodecanediol di(meth)acrylate, propylene glycol di(meth)acrylates, ethylene glycol di(meth)acrylates, hydroxy pivalic acid neopentyl glycol di(meth)acrylate, neopentyl glycol di(meth)acrylate, bisphenol A di(meth)acrylates, tricyclodecanedimethanol di(meth)acrylate, poly(ethylene glycol) di(meth)acrylates, polybutadiene di(meth)acrylate, polyurethane di(meth)acrylates, and glycerin tri(meth)acrylate, trimethylolpropane tri(meth)acrylate, tris(2-hydroxyethyl)isocyanurate triacrylate, pentaerythritol tri- and tetra(meth)acrylate and, ditrimethylolpropane tetra(meth)acrylate, dipentaerythritol penta(meth)acrylate, dipentaerythritol hexa(meth)acrylate, ethoxylated and propoxylated versions and mixtures thereof.

The amount of free-radically polymerizable monomer is represented by the formula

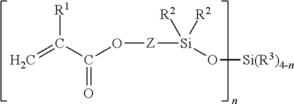

described above in the polymerizable composition is typically 0.01 to 40 weight percent (wt. %), preferably 0.1 to 30 wt. %, and more preferably 1 to 20 wt. % based on the total weight of the composition, although other amounts may also be used.

The amount of additional free-radical polymerizable monomer is typically about 60 to about 99 percent, although greater and lesser amounts may also be used.

The free-radically polymerizable composition also comprises at least one free-radical polymerization initiator (commonly called a free-radical initiator). Exemplary free-radical initiators include thermal free-radical initiators, free-radical photoinitiators, and redox free-radical initiators. Often the free-radical initiator comprises a photoinitiator, especially if the free-radically polymerizable composition is formulated into an inkjet ink. The free-radical initiator is present in the free radically polymerizable composition in at least an amount that is effective to cause a desired degree of polymerization. Often that amount is 0.1 to 5 weight percent of the free-radically polymerizable composition, however greater and lesser amounts may also be used.

Free-radical photoinitiators are activated by light, typically ultraviolet (UV) and/or visible light, to produce free-radicals. Exemplary light sources include low-, medium-, and high-pressure mercury arc lamps, microwave driven mercury lamps (e.g., using H-type or D-type bulbs), light emitting diode (LEDs), lasers, and xenon flashlamps.

Suitable free-radical polymerization initiators may include, for example, free-radical thermal and/or photoinitiators. Exemplary free-radical thermal initiators include organic peroxides (e.g., diacyl peroxides, peroxy ketals, ketone peroxides, hydroperoxides, dialkyl peroxides, peroxy esters, and peroxydicarbonates) and azo compounds (e.g., azobis(isobutyronitrile)). Examples of free-radical photoinitiators include: 2-benzyl-2-(dimethylamino)-4′-morpholinobutyrophenone; 1-hydroxycyclohexyl-phenyl ketone; 2-methyl-1-[4-(methylthio)phenyl]-2-morpholinopropan-1-one; 4-methylbenzophenone; 4-phenylbenzophenone; 2-hydroxy-2-methyl-1-phenylpropanone; 1-[4-(2-hydroxyethoxyl)-phenyl]-2-hydroxy-2-methylpropanone; 2,2-dimethoxy-2-phenylacetophenone; 4-(4-methylphenylthio)benzo-phenone; benzophenone; 2,4-diethylthioxanthone; 4,4′-bis(diethylamino)benzophenone; 2-isopropyl-thioxanthone; acylphosphine oxide derivatives, acylphosphinate derivatives, and acylphosphine derivatives (e.g., phenylbis(2,4,6-trimethylbenzoyl)phosphine oxide (available as OMNIRAD 819 from IGM Resins, St. Charles, Illinois), phenylbis(2,4,6-trimethylbenzoyl)phosphine (e.g., as available as OMNIRAD 2100 from IGM Resins), bis(2,4,6-trimethylbenzoyl)phenylphosphine oxide, 2,4,6-trimethylbenzoyldiphenylphosphine oxide (e.g., as available as OMNIRAD 8953X from IGM Resins), isopropoxyphenyl-2,4,6-trimethylbenzoylphosphine oxide, dimethyl pivaloylphosphonate), ethyl (2,4,6-trimethylbenzoyl) phenyl phosphinate (e.g., as available as OMNIRAD TPO-L from IGM Resins); bis(cyclopentadienyl) bis[2,6-difluoro-3-(1-pyrryl)phenyl]titanium (e.g., as available as OMNIRAD 784 from IGM Resins); and combinations thereof.

The free-radically polymerizable composition may include additional components such as, for example, wetting agents, antioxidants, adhesion promoters, colorants, and organic solvent. Amounts of such components will vary depending on intended use, but selection and optimization of the additives and their amounts are within the capability of those skilled in the art.

Free-radically polymerizable compositions according to the present disclosure may be dispensed/coated onto a substrate by any suitable method including, for example, screen printing, inkjet printing, flexographic printing, and stencil printing. Of these, inkjet printing (e.g., thermal inkjet printing or piezo inkjet printing) is particularly well-suited for use with the polymerizable compositions according to the present disclosure. To be useful in inkjet printing techniques, preferably the polymerizable composition is formulated to be substantially solvent free (e.g., compositions having less than 5 wt. %, 4 wt. %, 3 wt. %, 2 wt. %, 1 wt. % and 0.5 wt. % of organic solvent), although organic solvent may be included.

Inkjet printing may be carried out over a range of temperatures (e.g., 20° C. to 60° C.). Inkjet printable polymerizable compositions should typically have a shear viscosity of less than about 100 centipoise, preferably less than 50 centipoise, more preferably less than 30 centipoise, and most preferably less than 20 centipoise at the printing temperature; for example as measured by ASTM Test Method D7867-13(2020) (Standard Test Methods for Measurement of the Rotational Viscosity of Paints, Inks and Related Liquid Materials as a Function of Temperature).

Free-radical polymerization may be accomplished/accelerated by heating (e.g., in an oven or by exposure to infrared radiation) and/or exposure to actinic radiation (e.g., ultraviolet and/or electromagnetic visible radiation), for example. Selection of sources of actinic radiation (e.g., xenon flash lamp, medium pressure mercury arc lamp) and exposure conditions is within the capability of those having ordinary skill in the art.

Generally, simple mixing techniques are sufficient to mix the components of the free-radically polymerizable composition.

In some embodiments, free-radically polymerizable compositions according to the present disclosure are formulated as inks (e.g., screen printing inks or inkjet printable inks) or other dispensable fluids that can be applied to substrates such as electronic displays and optical electronic components thereof, for example. As printed and/or polymerized the deposited ink layer may have a thickness of 4 to 20 microns, preferably 4 to 10 microns, although other thicknesses may also be used. Examples include Organic Light Emitting Diodes (OLEDs), Quantum Dot Light Emitting Diodes (QDLEDs), Micro Light Emitting Diodes (pLEDs), and Quantum Nanorod Electronic Devices (QNEDs). Advantageously, inkjet printable polymerizable compositions according to the present disclosure are suitable for use with optical electronic components due to their combination of low dielectric constant and tailorable refractive index.

Polymerizable compositions according to the present disclosure can be disposed on a substrate and at least partially polymerized/cured (e.g., cured to a B or C-stage) to provide an electronic article including an optical electronic component such as, for example, as OLED display.

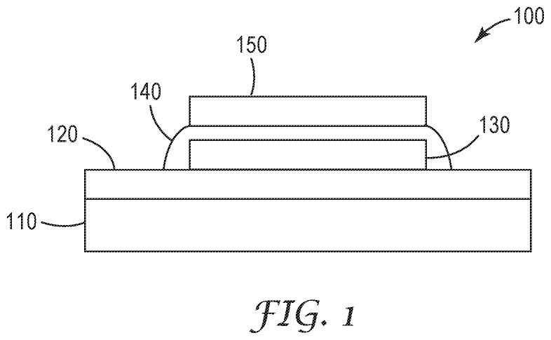

Referring now to FIG. 1, exemplary electronic device 100 comprises an optical electronic component in the form of OLED display 130 supported on Thin Film Transistor (TFT) 120 array on an OLED mother glass substrate 110. Thin Film Encapsulation (TFE) layer 140 comprises an at least partially polymerized composition according to the present disclosure composition 140 that together with the OLED mother glass substrate 110 encases OLED display 130. Touch sensor assembly (e.g., an On-Cell Touch Assembly (OCTA)) 150 is disposed on cured composition 140. In many embodiments, silicon nitride barrier layers (not shown) are present between OLED display 130 and TFE layer 140 and between TFE layer 140 and touch sensor display 150, although this is not a requirement.

Due to the close proximity of the touch sensor and the OLED/TFT array, the electronic signals from the OLED display have a potential to interfere with the touch sensor (e.g., OCTA). Hence, the cured composition in the TFE requires a lower dielectric constant in order to electronically isolate the OCTA layer from the OLED and improve touch sensitivity in the device. If the dielectric constant of the cured composition is too large (e.g., >4 at 1 MHz), very thick layers of the TFE would be required to reach the low capacitance per unit area typical of capacitive touch sensors. Conversely, a low dielectric constant material (e.g., <3 at 1 MHz), permits the TFE layer to be only a few microns thick while still serving the function of electronic isolation between the OLED and the OCTA layers. Such thin TFE layers are also easier and faster to print than thicker layers, and have better overall optical properties.

Objects and advantages of this disclosure are further illustrated by the following non-limiting examples, but the particular materials and amounts thereof recited in these examples, as well as other conditions and details, should not be construed to unduly limit this disclosure.

### EXAMPLES

Unless otherwise noted, all pants, percentages, ratios, etc. in the Examples and the rest of the specification are by weight. Abbreviations and descriptions of materials used in the Examples are reported in Table 1, below.

TABLE 1

| MATERIAL | ABBREVIATION | SOURCE |
|---|---|---|
| Tetrakis(dimethylsiloxy)silane | — | Product No. SIT7278.0, Gelest, |
| | | Inc., Morrisville, Pennsylvania |
| Methyltri(dimethylsiloxy)silane | — | Product no. AB111250, ABCR, |
| | | Karlsruhe, Germany |
| Phenyltri(dimethylsiloxy)silane | — | Product No. 448648, |
| | | MilliporeSigma, Burlington, |
| | | Massachusetts |
| Trifluoropropyltris(dimethylsiloxy)silane, | | Product No. SIT8372.4, Gelest, |
| equivalent to 3-(dimethylsiloxy)-1,1,5,5- | | Inc. |
| tetramethyl-3-(3,3,3-trifluoropropyl) trisiloxane | | |
| Platinum divinyltetramethyldisiloxane complex | — | Product No. SIP6830.3, Gelest, |
| (3 wt. % in vinyl-terminated PDMS) | | Inc. |
| Allyl methacrylate | — | Product No. M0075, TCI America, |
| | | Portland, Oregon |
| Hydroxy pivalic acid neopentyl glycol | HPNDA | MIRAMER M210, Miwon, Exton, |
| diacrylate | | Pennsylvania |
| 1,10-decanediol diacrylate | DDA | MIRAMER M2010, Miwon |
| Acrylate esters based off of an aliphatic | CN309 | CN309 from Sartomer Co. |
| hydrophobic backbone | | |
| Diphenyl(2,4,6-trimethylbenzoyl)phosphine | TPO | OMNIRAD-TPO from GM Resins |
| oxide | | USA, Inc., Charlotte, North |
| | | Carolina |
| Isostearyl acrylate | ISTA | NK-ESTER S1800ALC from |
| | | Shin-Nakamura (Tokyo, Japan) |
| Isobornyl acrylate | IBOA | MIRAMER. M1140 from Miwon |
| Tricyclodecanedimethanol diacrylate | TAcrylat | T-ACRYLAT from 3M ESPE, |
| | | Seefeldt, Germany |
| Propoxylated trimethylolpropane triacrylate | M360 | MIRAMER M360 from Miwon |
| Fluorosilicone coated polyester film liner | L1 | SILFLU M117 from |
| | | SILICONATURE USA, LLC, |
| | | Chicago, Illinois |
| Fluorosilicone coated polyester film liner | L2 | Product no. 5199 from Loparex, |
| | | Cary, North Carolina |

### ¹H Nuclear Magnetic Resonance (NMR) Analysis

Specimens were analyzed as solutions in deuterated chloroform. ¹H NMR analysis was conducted using a Bruker AVANCE III 500 MHz NMR spectrometer equipped with a CPBBO gradient cryoprobe, a Bruker B-ACS 60 autosampler, and Bruker Topspin 3.04 software. Spectra were analyzed using Advanced Chemistry Development software, Toronto, Canada.

### Measurement of Refractive Index

Refractive index was measured on a Milton Roy Company refractometer (model number: 334610). The liquid sample was sealed between two prisms and the refractive index was measured at 20° C. at the 589 nm line of a sodium lamp.

### Example 1

### Synthesis of Methacrylate 1(M1)

Tetrakis(dimethylsiloxy)silane (4.48 grams, 0.0136 mol) was added dropwise to a stirred solution of allyl methacrylate (7.57 grams, 0.0600 mol) and platinum divinyltetramethyldisiloxane complex (1 drop, 3 wt. % Pt in vinyl-terminated polydimethylsiloxane) in toluene (50 mL). The reaction mixture was cooled to maintain temperature below 50° C. for 30 minutes, and then the reaction mixture was stirred at 60° C. for 3 days. Toluene was removed in vacuo to give the product as a colorless liquid, and as a mixture of regio-isomers confirmed by NMR analysis. Refractive index=1.431.

### Example 2

### Synthesis of Methacrylate 2 (M2)

Methyltri(dimethylsiloxy)silane (0.78 grams, 2.90 mmol) was added dropwise to a stirred solution of allyl methacrylate (1.21 grams, 9.58 mmol) and platinum divinyltetramethyldisiloxane complex (1 drop, 3 wt. % Pt in vinyl-terminated polydimethylsiloxane) in toluene (20 mL). The reaction mixture was cooled to maintain temperature below 50° C. for 30 minutes, and then the reaction mixture was stirred at 60° C. for 2 days. Toluene was removed in vacuo to give the product as a colorless liquid, and as a mixture of regio-isomers confirmed by NMR analysis. Refractive index=1.429.

### Example 3

### Synthesis of Methacrylate 3 (M3)

Phenyltri(dimethylsiloxy)silane (10.67 grams, 0.0322 mol) was added dropwise to a stirred solution of allyl methacrylate (12.21 grams, 0.0968 mol) and platinum divinyltetramethyldisiloxane complex (1 drop, 3 wt. % Pt in vinyl-terminated polydimethylsiloxane) in toluene (100 mL). After an initial exotherm, the reaction mixture was stirred at 60° C. for 3 days. Toluene was removed in vacuo to give the product as a colorless oil, and as a mixture of regio-isomers confirmed by NMR analysis. Refractive index=1.460.

### Example 4

### Synthesis of Methacrylate 4 (M4)

Trifluoropropyltris(dimethylsiloxy)silane (10.18 grams, 0.0290 mol) was added dropwise to a stirred solution of allyl methacrylate (10.99 grams, 0.0871 mol) and platinum divinyltetramethyldisiloxane complex (1 drop, 3 wt. % Pt in vinyl-terminated polydimethylsiloxane) in toluene (100 mL). The reaction mixture was cooled to maintain temperature below 50° C. for 30 minutes, and then the reaction mixture was stirred at 60° C. for 3 days. Toluene was removed in vacuo to give the product as a pale yellow liquid, and as a mixture of regio-isomers confirmed by NMR analysis. Refractive index=1.427.

### Examples 5-10 and Comparative Examples CE-A and CE-B

Ink Formulations were prepared as follows: Omnirad TPO (1 part by weight per hundred parts resin (phr)) was added to the formulations in Table 2, and they were sonicated until a homogenous solution was formed. After purging in a chamber filled with a nitrogen atmosphere for 90 seconds, the formulations were cured using a 395 nm UV-LED light (Phoseon FJ200) unit at 500 mW/cm2 for 30 seconds to form transparent hard coats.

TABLE 2

| EXAMPLE | COMPONENT, phr | | | | | | | | | | |
|---|---|---|---|---|---|---|---|---|---|---|---|
| (INK) | M1 | M2 | M3 | M4 | CN309 | HPNDA | DDA | ISTA | IBOA | TAcrylat | M360 |
| 5 | 100 | 0 | 0 | 0 | 0 | 0 | 0 | 0 | 0 | 0 | 0 |
| 6 | 0 | 100 | 0 | 0 | 0 | 0 | 0 | 0 | 0 | 0 | 0 |
| 7 | 0 | 0 | 100 | 0 | 0 | 0 | 0 | 0 | 0 | 0 | 0 |
| 8 | 0 | 0 | 0 | 100 | 0 | 0 | 0 | 0 | 0 | 0 | 0 |
| 9 | 20 | 0 | 0 | 0 | 0 | 40 | 40 | 0 | 0 | 0 | 0 |
| 10 | 0 | 0 | 20 | 0 | 0 | 40 | 40 | 0 | 0 | 0 | 0 |
| CE-A | 0 | 0 | 0 | 0 | 20 | 40 | 40 | 0 | 0 | 0 | 0 |
| CE-B | 0 | 0 | 0 | 0 | 0 | 0 | 0 | 40 | 40 | 15 | 5 |

### Measurement of Glass Transition Temperature

Formulations were cured in a mold measuring approximately 1 mm thick, 5 mm wide and 10-12 mm long. A Dynamic Mechanical Analyzer (DMA) (Q800, TA Instruments, New Castle, Delaware) was used in “Multi-Frequency—Strain” mode. The sample was run at 1 kHz frequency under a temperature sweep from ambient to 160.00° C. at 3.00° C./min. The glass transition temperature (Tg) was captured as the peak of the tan delta curve. Results are reported in Table 3.

### Measurement of Dielectric Constant

Cured thick films of ink formulations were prepared for the dielectric spectroscopic measurement. The films were made by first taping easy and premium release liners to 5 in x 5 in (12.7 cm×12.7 cm) borosilicate glass plates. L1 was used as the easy release liner, and L2 was used as the premium release liner. A 400 micron thick Teflon sheet with a 3 in (7.6 cm) diameter circle punched out of the center, along with a side injection port was clamped in between the two release liners. Three mL of each of the formulations were injected with a pipette into the construction via the injection port. The construction was clamped with binder clips and cured with a UV-LED light with 395 nm wavelength (FJ801, Phoseon Technologies, Hillsboro, Oregon, 30 seconds per side, for a total radiation dose of ˜14 J/cm². The samples were carefully removed from the cell and peeled from the liners.

The dielectric properties and electrical conductivity measurements were performed with an Alpha-A High Temperature Broadband Dielectric Spectrometer modular measurement system from Novocontrol Technologies Gmbh (Montabaur, Germany). All testing was performed in accordance with the ASTM D150 test standard. The films were painted with copper paint. The Novocontrol ZGS Alpha Active Sample Cell was implemented once each sample was placed between two optically polished brass disks (diameter 40.0 mm and thickness 2.00 mm). Results are reported in Table 3, below.

TABLE 3

| | | | DIELECTRIC |
|---|---|---|---|
| | | T_{g}, | CONSTANT AT |
| EXAMPLE | APPEARANCE, | POST-CURE, | 1 MHz, |
| (INK) | POST-CURE | ° C. | POST-CURE |
| 9 | Transparent | 131 | 3.58 |
| | hardcoat | | |
| 10 | Transparent | 116 | 3.48 |
| | hardcoat | | |
| CE-A | Transparent | 108 | 2.77 |
| | hardcoat | | |
| CE-B | Transparent | 76 | 2.60 |
| | hardcoat | | |

### Plasma Etch Testing

A silicon wafer (4-inch (10-cm) diameter, University Wafer, Boston, Massachusetts) was cleaned with acetone and isopropanol. The silicon wafer was placed on a hot plate at 250° C. for 10 min to dehydrate, then ozone treated for 5 minutes (Novascan PSD Pro series Digital UV ozone System). Example Formulations, as described by Table 2, were coated onto the wafers using a film applicator bar (BYK Additives and Instruments, Wesel Germany, Model 46245) and cured under a 395 nm UV-LED light (Phoseon Technologies FJ801 Controller) after a 90 second N₂ purge.

The samples were partially covered with tape (3M Polyester Green Tape, product number 8403, 3M Company) and treated with oxygen plasma for five minutes (Yield Engineering System G1000, Gas=100% O₂, Flow=60 sccm, RF Power=300W, Time=300 seconds). The tape was removed, and the sample was analyzed with white light interferometry (Contour GTX-8, Bruker Inc., Billerica, Massachusetts) at the interface of the film area that was partially covered with tape. Vision 64 software and its “modal tilt only” function were used to level the data in order to calculate the step edge (Bruker Inc., Billerica, Massachusetts) and determine the step height. The Comparative Example CE-B showed significant etching as a result of exposure to plasma relative to the side of the sample that was covered with tape (“unetched”) during the exposure to plasma. An ink formulation with the etch-resistant additive, Example (ink) 9 showed no significant etching as a result of exposure to plasma when comparing the etched to the unetched side of the film. Table 4, below, reports etch depth after five minutes exposure to oxygen plasma and calculated etch rate

TABLE 4

| | STEP HEIGHT, | ETCH RATE |
|---|---|---|
| EXAMPLE | microns | nanometers/minute) |
| CE-B | 0.2211 | 44.2 |
| E9 | 0.0011 | 0.22 |

The preceding description, given in order to enable one of ordinary skill in the art to practice the claimed disclosure, is not to be construed as limiting the scope of the disclosure, which is defined by the claims and all equivalents thereto.

1. A free-radically polymerizable monomer represented by the formula 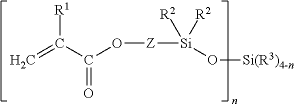
wherein:
each Z independently represents a divalent aliphatic hydrocarbylene group having 3 to 12 carbon atoms;
each R¹ independently represents H or methyl;
each R² independently represents a hydrocarbyl group having from 1 to 6 carbon atoms;
R³ represents methyl, phenyl, or —CH₂CH₂CF₃; and
n is 3 or 4.

2. The free-radically polymerizable monomer of claim 1, wherein each Z is a propanediyl.

3. The free-radically polymerizable monomer of claim 1, wherein R³ represents methyl.

4. The free-radically polymerizable monomer of claim 1, wherein R³ represents phenyl.

5. The free-radically polymerizable monomer of claim 1, wherein R³ represents —CH₂CH₂CF₃.

6. The free-radically polymerizable monomer of claim 1, wherein each R¹ represents methyl.

7. A free-radically polymerizable composition comprising:
i) a free-radically polymerizable monomer represented by the formula 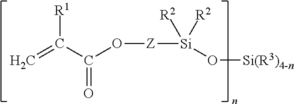
wherein:
each Z independently represents a divalent aliphatic hydrocarbylene group having 3 to 12 carbon atoms;
each R¹ independently represents H or methyl;
each R² independently represents a hydrocarbyl group having from 1 to 6 carbon atoms;
R³ represents methyl, phenyl, or —CH₂CH₂CF₃; and
n is 3 or 4; and
ii) a free-radical polymerization initiator.

8. The free-radically polymerizable composition of claim 7, further comprising at least one additional free-radically polymerizable monomer.

9. The free-radically polymerizable composition of claim 7, wherein each Z is a propanediyl.

10. The free-radically polymerizable composition of claim 7, wherein R³ represents methyl.

11. The free-radically polymerizable composition of claim 7, wherein R³ represents phenyl.

12. The free-radically polymerizable composition of claim 7, wherein R³ represents —CH₂CH₂CF₃.

13. The free-radically polymerizable composition of claim 7, wherein each R¹ represents methyl.

14. The free-radically polymerizable composition of claim 7, wherein the free-radically polymerizable composition has a dynamic viscosity of less than or equal to 100 centipoise (0.1 pascal second) at 25° C.

15. The free-radically polymerizable composition of claim 7, wherein the free-radical polymerization initiator comprises a photoinitiator.

16. A method of using the free-radically polymerizable composition of claim 7, the method comprising disposing the free-radically polymerizable composition on a substrate, and
decomposing at least a portion of the free-radical polymerization initiator thereby causing at least partial polymerization of the free-radically polymerizable composition.

17. The method of claim 16, wherein the substrate comprises an optical electronic component.

18. The method of claim 16, wherein the electronic display component comprises an organic light emitting diode.

19. The method of claim 16, wherein said disposing the free-radically polymerizable composition on the substrate comprises inkjet printing.

20. An at least partially polymerized free-radically polymerizable composition according to any of claim 7.

21.-23. (canceled)
